(19) United States
(12) Patent Application Publication
(10) Pub. No.: US 2025/0366269 A1
(43) Pub. Date: Nov. 27, 2025

(54) SHAPED SURFACE LUMINANCE LED WITH ADJUSTABLE LUMINANCE GRADIENT

(71) Applicant: LUMILEDS LLC, San Jose, CA (US)

(72) Inventors: Florent MONESTIER, Eindhoven (NL); Jeff DiMaria, Scotts Valley, CA (US)

(73) Assignee: LUMILEDS LLC, San Jose, CA (US)

(21) Appl. No.: 19/198,996

(22) Filed: May 5, 2025

Related U.S. Application Data
(63) Continuation of application No. PCT/US2023/081911, filed on Nov. 30, 2023.
(60) Provisional application No. 63/433,297, filed on Dec. 16, 2022.

(51) Int. Cl. H10H 20/831

(52) U.S. Cl. CPC H10H 20/8316

(57) ABSTRACT

This specification discloses light emitting devices electrical contacts that improve performance and clarity to operators of the light emitting devices. A small number of electrical contacts includes two or three contacts that may be independent driven from one another to obtain a desired luminance profile. The forward voltage V_{f} and internal quantum efficiency (IQE) may be easily known with the devices and methods described in this specification, allowing for ease-of-use combined with adaptability.

### CROSS REFERENCE TO RELATED APPLICATIONS

This application is a continuation of PCT Application PCT US2023/081911 filed on Nov. 30, 2023, which claims benefit of priority to U.S. Provisional Patent Application No. 63/433,297 filed on Dec. 16, 2022. Both of the above applications are incorporated by reference in this application in their entirety.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, matrices and light engines including automotive adaptive headlights, augmented-reality (AR) displays, virtual-reality (VR) displays, mixed-reality (MR) displays (AR, VR, and MR systems referred to herein as visualization systems), smart glasses and displays for mobile phones, smart watches, monitors and TVs, and flash illumination for cameras in mobile phones. Individual LEDs or pcLEDs in these architectures can have an area of a few square millimeters down to a few square micrometers (e.g., microLEDs) depending on the matrix or display sized and its pixel per inch requirements.

Such LEDs and pcLEDs may be arranged in arrays for use, for example, in automotive vehicles, and for general illumination including indoor and outdoors. Specifically, certain of these LEDs and pcLEDs may be shaped to have a specific luminance profile with a luminance gradient and/or region with peak luminance. Particularly, these multi-die packages with these LEDs and pcLEDs may be useful for high and low beam applications in automotive headlights. Analysis of some automotive system optics suggests that a shaped surface luminance, where the center is peaked or with a gradient from one side to another side has the best system optics efficiency, indicated by the system optics figure of merit (FOM).

The ideal luminance shape will depend on many parameters such as system optics, application field and operating conditions. Different degrees of luminance profiles may be present for edge shift luminance die (ESL) and center peak luminance die (CPL). FIG. 11 depicts dies with different luminance profiles. The first row shows ESL dies, and the second row shows CPL dies with different gradient between peak luminance and opposite sides, and the corresponding Internal Quantum Efficiency (IQE) and forward voltage Vf. Note that IQE and Vf penalty will depend strongly on the level of operating current.

Many automotive set-makers are using custom designed system optics with a specific arrangement and shape of board, primary and secondary optics, and LED count. Ultimately, all head-lamps are different and there is no ideal surface luminance distribution that will fit all systems. The compromise between luminance gradient, IQE drop and Vf increase will also depend strongly on the application and operating condition. It is therefore beneficial to leave the end user the possibility to adapt dynamically the surface luminance profile to fit specific system optics requirements, operating & application conditions.

A shaped luminance profile die is defined as a die where the luminance averaged over an area equal to at least 10% of the whole light emitting area deviates 20% or more of the mean luminance averaged over the whole light emitting area. When the deviation involves more luminance, this area may be called the peak luminance area.

Usually dynamic driving of the luminance shape is obtained by feeding or adding more current to different segments or regions of the die. A typical way of generating different luminance profiles with the same die involves a multitude of contact paths—e.g., greater than three—that cause too abrupt a change. These existing methods have strong impact on IQE drop and V_{f} increase. The drop of IQE is mainly created by current crowding and lower IQE at higher current.

Another disadvantage of dynamic change of light emitting area (LEA) with an undefined or large number of electrical contacts is that it leaves too many driving possibilities to the end user without clear guidance how to reach the desired luminance profile and how to minimize the impact on IQE and Vf. Furthermore, with so many electrical contacts, much spacing will be needed between electrical contacts. As a result, interconnect area will be very low and therefore thermal resistance (Rth) will be very high. What is needed are methods and devices providing simplified and clear driving possibilities adaptable to different luminance profiles.

### SUMMARY

This specification discloses methods and devices of driving current into a die with a small number of electrical contacts coming off the die (e.g., three or four) which provide increased efficiency when tuning the shaped luminance of the described dies. The dies may have two or three n sided electrical contacts that may be independently driven from each other to provide good adaptability to different desired luminance profiles. This approach provides increased clarity to the operator of the die on what type of profiles can be obtained, and at what cost to performance.

This invention can be used in any automotive headlamps where a single- or multi-die package is needed. It is preferably use in multi die package where surface luminance distribution of each die is intentionally not uniform and where large electrical pads have to cover fully the area where the peak current is generated to reduce thermal resistance.

Other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of LEDs or pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6A shows a top view of a bonding structures on the n side where they may contact a semiconductor diode structure. FIG. 6B shows the dielectric layer between the two n sides of the bonding structures and one p side of the bonding structures. FIG. 6C shows the electrical contacts coming off the die connected to the bonding structures.

FIG. 7 shows a cross section of the die, including the epitaxial layer, the bonding structures, and the two types of n contacts and one type of p contact.

FIG. 8A shows a top view of a bonding structures on the n side where they may contact a semiconductor diode structure. FIG. 8B shows the dielectric layer between the two n sides of the bonding structures and one p side of the bonding structures. FIG. 8C shows the electrical contacts coming off the die connected to the bonding structures.

FIG. 9 shows a cross section of a package where one of the two n contacts is wired bonded rather than soldered under the semiconductor diode structure.

FIG. 10 illustrates a top view of bonding structures with three bonding structures on the n side rather than two.

FIG. 11 depicts dies with different luminance profiles.

FIG. 12 illustrates how peakiness of an edge shifted luminance die may be adjusted by current adjustment to the two n contacts.

FIG. 13 illustrates a chart used as a basis to construct look-up tables allowing simplified adjustment of luminance profiles in embodiments of the invention.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate.

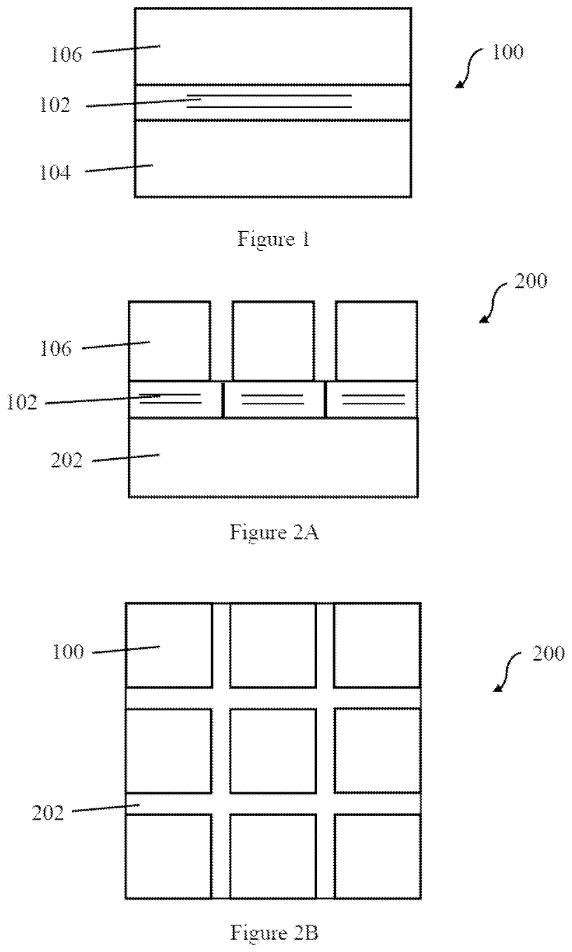

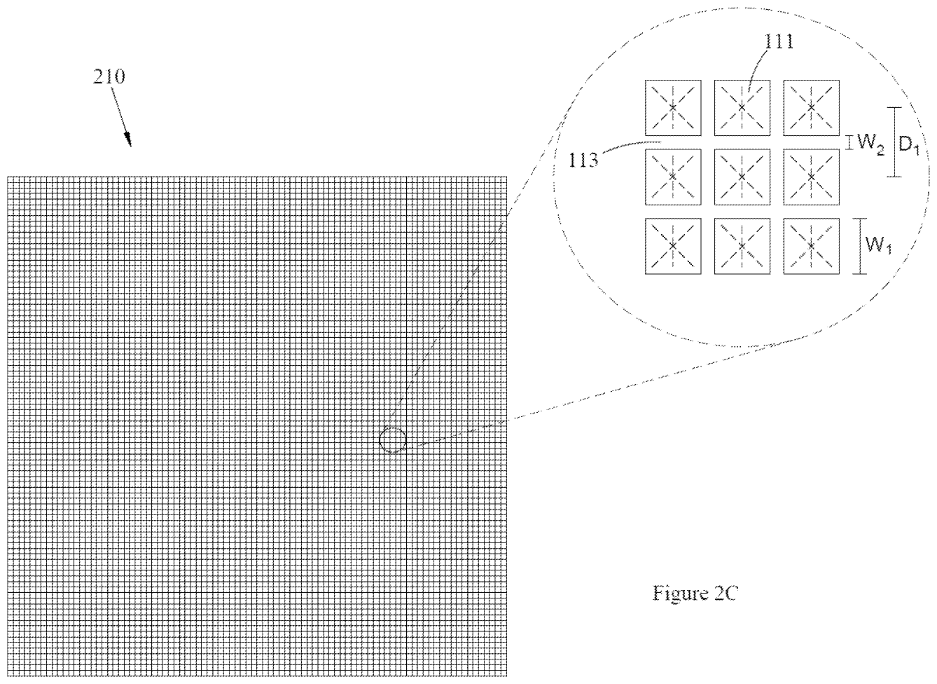

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 1 millimeter (mm), less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W1 are arranged as a square matrix with neighboring LEDs or pcLEDs having a center-to-center distances D1 and separated by lanes 113 having a width W2. W1 may be, for example, less than or equal to 1 millimeter (mm), less than or equal to 500 microns, less than or equal to 100 microns, less than or equal to 50 microns, or less than or equal to 10 microns. W2 may be, for example, hundreds of microns, less than or equal to 100 microns, less than or equal to 50 microns, less than or equal to 10 microns, or less than or equal to 5 microns. D1=W1+W2.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

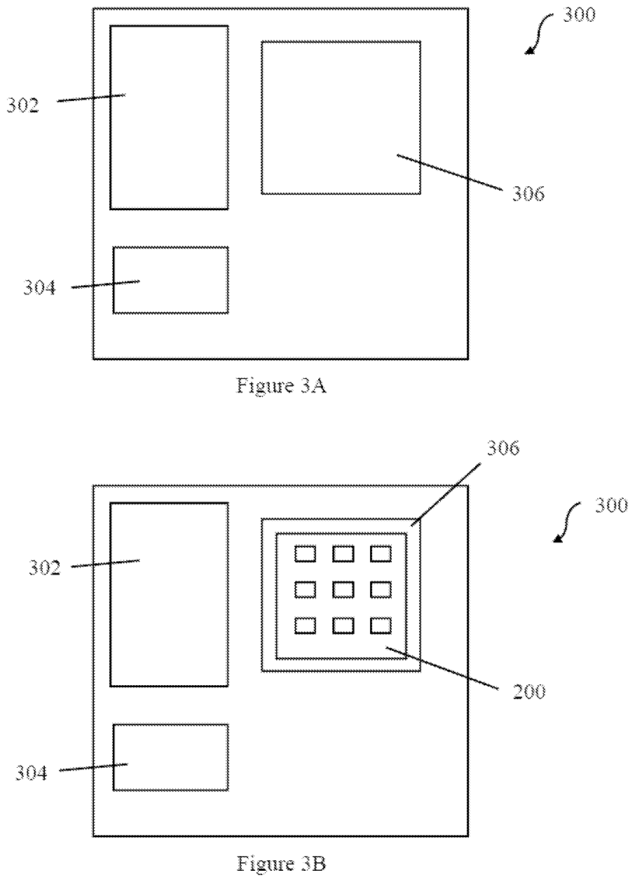

As shown in FIGS. 3A-3B, an LED or pcLED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

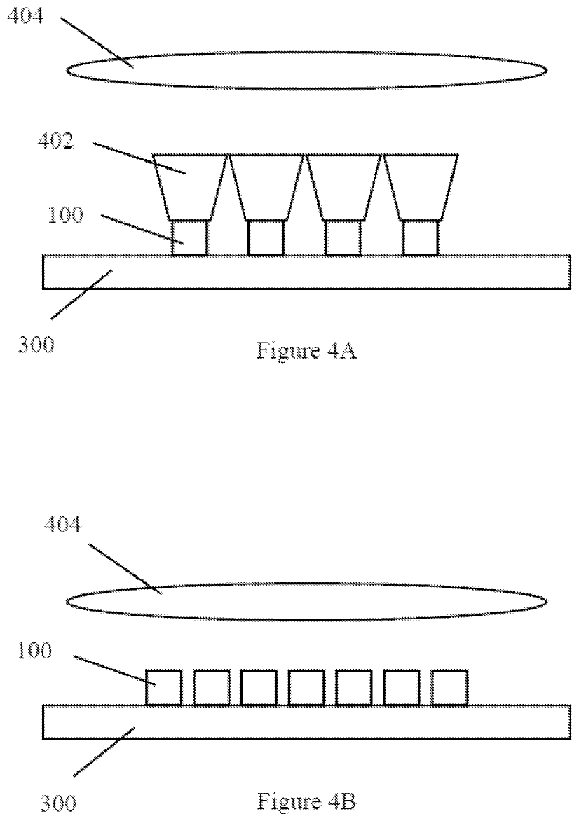

Individual LEDs or pcLEDs may optionally incorporate or be arranged in combination with a lens or other optical element located adjacent to or disposed on the LED or the phosphor layer of the pcLED. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distributions. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), AR, VR, and MR applications such as those described below.

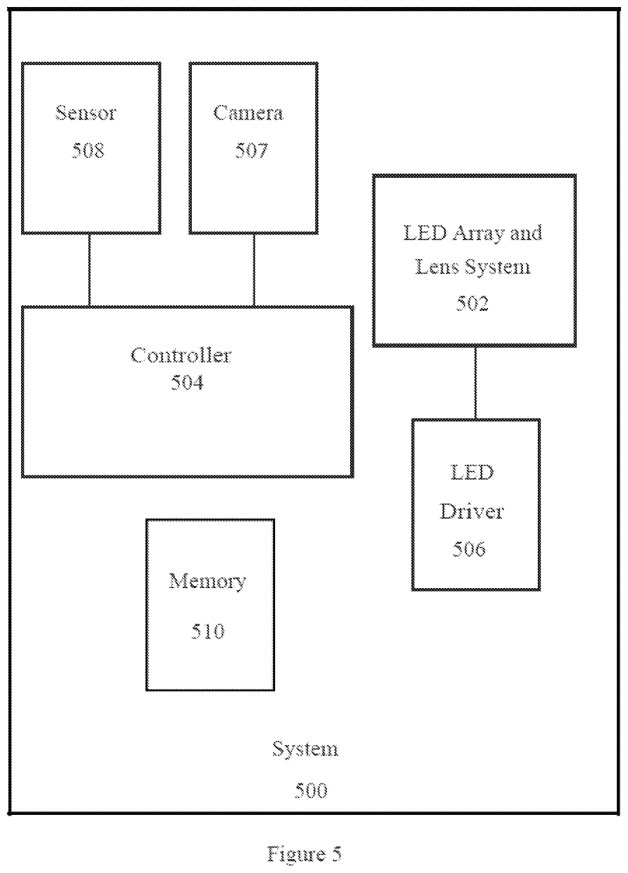

FIG. 5 schematically illustrates an example camera flash system 500 comprising an LED or pcLED array and an optical (e.g., lens) system 502, which may be or comprise an adaptive lighting system as described above in which LEDs or pcLEDs in the array may be individually operable or operable as groups. In operation of the camera flash system, illumination from some or all of the LEDs or pcLEDs in array and optical system 502 may be adjusted—deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

As mentioned above, shaped luminance dies in particular are useful for a number of applications. Shaped luminance may be achieved with a multitude of contact paths into the die. However, if there are too many contact paths this may cause current crowding and a decrease in efficiency.

To reduce the risk of drastic current crowding and associated uncontrolled V_{f} increase when altering surface luminance distribution of shaped luminance die, embodiments of the present invention include a specific die design with adjustable luminance gradient. These methods and devices may comprise balancing independently driven current (e.g., of different magnitudes) between two paths on the n side. One path is the center n contact connecting all etched areas situated within the die area, and the other path is the n outer contact situated along the outer mesa etched area. By balancing the current between center n contact and n contact edge, it is possible to change the luminance profile smoothly and minimize negative impact on IQE and V_{f} without the need to add an excessive amount of n Vias (i.e., bonding structures through the p-type layer and insulated by a first dielectric layer), increase the size of n Vias, or segment the die into many individual small parts individually controllable to get a specific luminance gradient. This allows the users of the die to tune the surface luminance profile to get the best system performances FOM while having low impact on IQE decrease and Vf increase. In addition, this reduces the risk of lower process yield due to non-periodic die patterning.

In a semiconductor die, electrical conductivity in the p-type layer or pGaN is generally lower than that of the n-type layer or nGaN. As a result, current may be injected uniformly in the pGaN layer to minimize V_{f} increase.

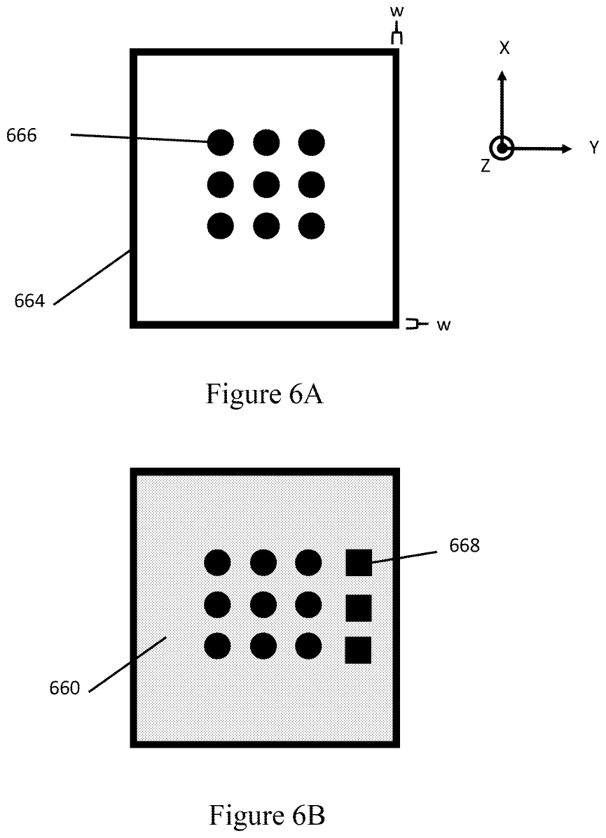

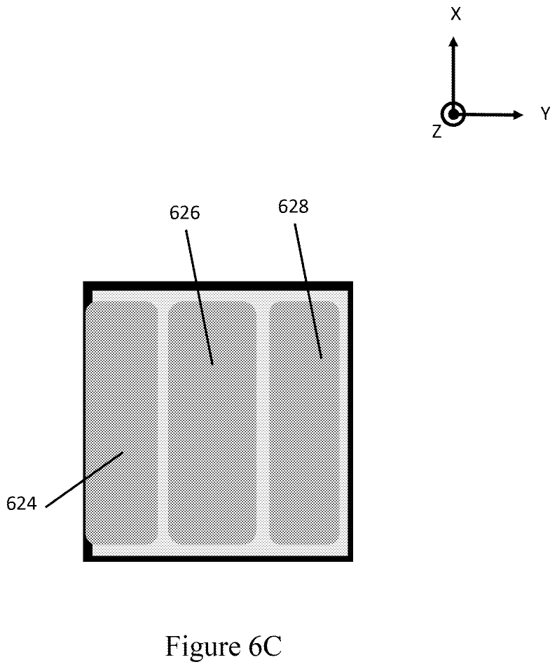

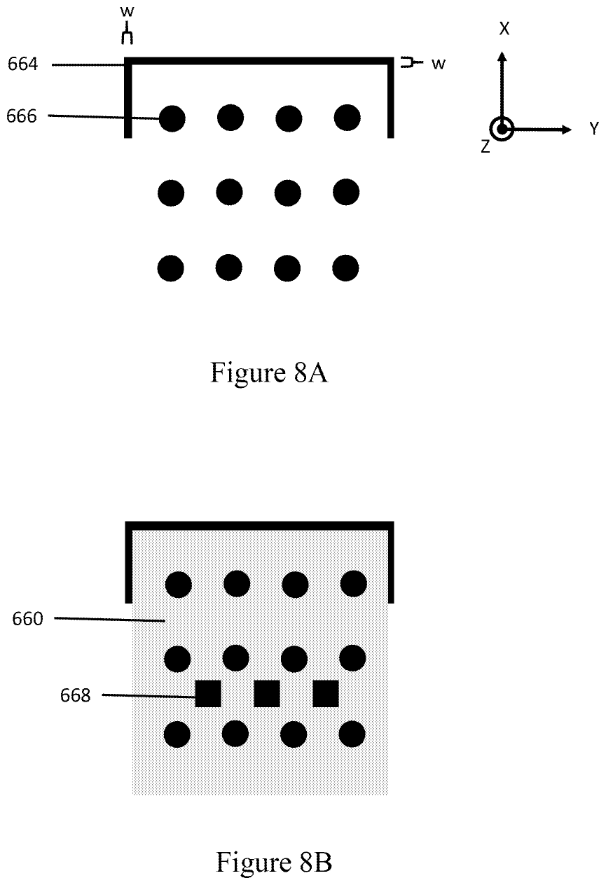

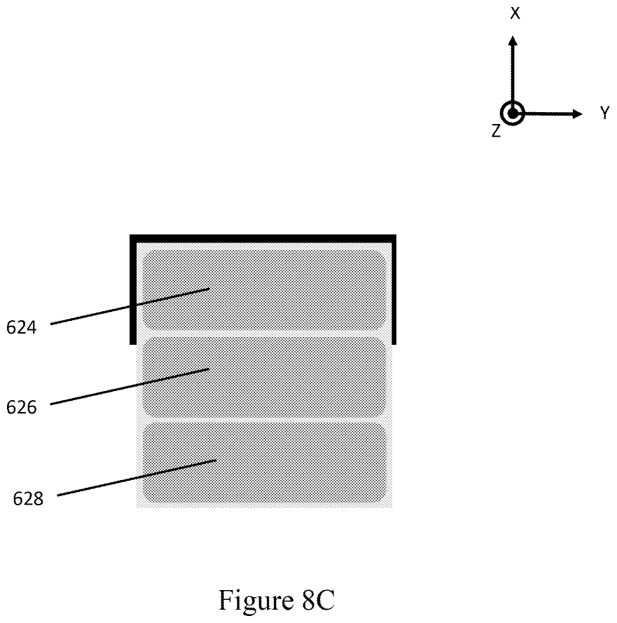

However, on the n side, the current will be injected via two different paths connected in parallel: the center n contacts and the n outer edge contact. The contact area with the epitaxial layer of the bonding structure in electrical connection with the n outer edge contacts can include all or part of the outer mesa etched area surrounding the die. This bonding structure may have a width w (shown in FIG. 6A or 8A) of few microns (such as from 1-50 microns, e.g., 1-10 microns) on the mesa etched area surrounding the active area of the die. The width may be measured perpendicular to the direction of respective edge of the epitaxial layer that the particular part of the bonding structure is adjacent to. The mesa may have the same width or a larger width, around the perimeter of the epitaxial layer.

In embodiments of the invention, FIG. 6A-6C shows a top view layout and current injection paths of n and p contacts and bonding structures that will be attached to an epitaxial layer, to make a die able to produce a CPL luminance profile. The n part of the bonding structure may be made of two different parts: one contacting only the center n Vias (i.e., the center bonding structure) and one part contacting only the n edge/outer area. With the p contacts that makes three electrical contacts in total coming off the die and attached to the driving circuit. Many other variations are possible. For example, the isolated n outer contact can also be connected to some n Vias.

FIG. 6A shows just the layout of the n bonding structure 664 and the center n Vias (n center bonding structure 666). The n outer bonding structure 664 may draw a square or rectangle that completely surrounds the n center bonding structures 666, which are spaced apart from each other in a A×B array, where A and B may be from 1 to 10, e.g. 3 as shown in FIG. 6A. The center n Vias can have any shape a circle, a rectangular slot, etc. This figure depicts just the part of the bonding structures that are in direct contact with the n-type layer 670. That is, the center n Vias of the n center bonding structures 666 are spaced apart from each other at least at the point of contact with the epitaxial layer. However, they may be connected all together so that they are all electrically conductive with one another, at a certain distance from the epitaxial layer.

FIG. 6B shows the first dielectric 660, which has openings for the n center bonding structures 666 and the p bonding structure 668. This first dielectric 660 spaces apart and isolates the n and p bonding structures from direct electrical connection with each other.

FIG. 6C show the n outer contacts 624, n center contacts 626, and p contacts 628 disposed below and respectively connected to the n and p bonding structures 664, 666, and 668.

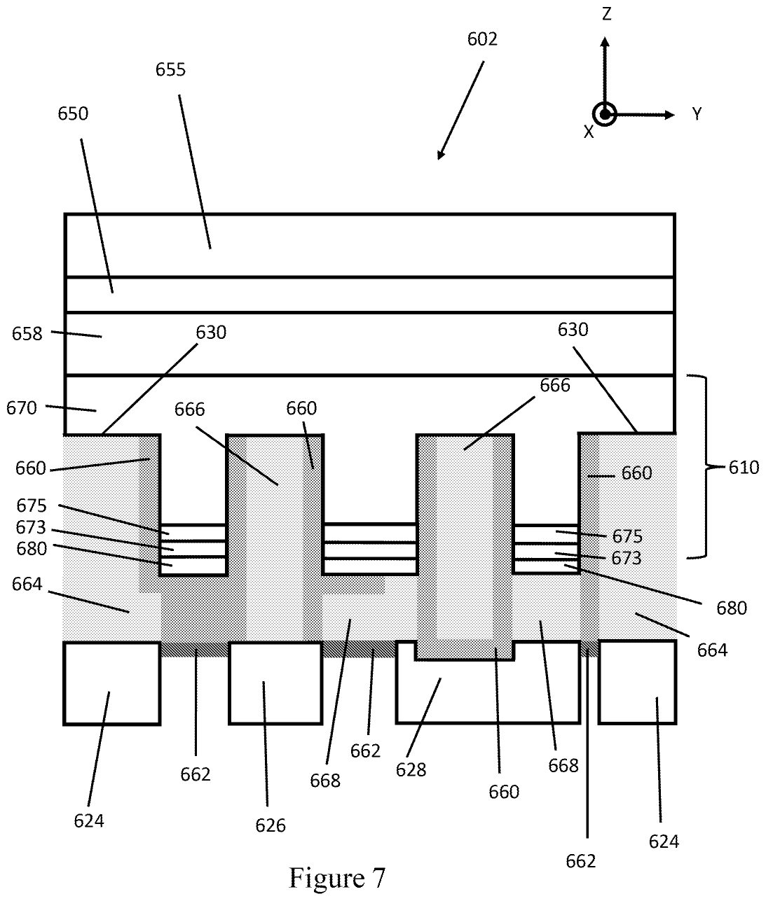

FIG. 7 shows a cross section of a die 602 with the electrical connections/pads similar or the same as FIG. 6 attached to an epitaxial layer and/or stack, particularly the connections of n outer contact 624, n center contact 626, and p contact 628. Each of the n outer contact 624 and the n center contact 626 may be driven with current independently from the other. The epitaxial layer 610 comprises an n-type layer 670 (e.g., nGaN), the quantum well 675, and the p-type layer 673 (e.g., pGaN). The n outer contact 624 may be a shape encircling the n center contact 626 and p contact 628. The n outer contact 624 is electrically connected to the n-type layer 670 through the n outer bonding structure 664, which are physically spaced apart from the p-type layer 673 by the first dielectric 665. The first dielectric 665 may be or comprise any of SiO₂, SiNₓ or TiOₓ, AlOₓ, NbOₓ; basically any material that is not electrically conductive and compatible with PECVD or ALD process. The n center contact 626 is electrically connected to the n-type layer through the n center bonding structure 666. The p contact 628 is electrically connected to the p-type layer by a p bonding structure 668. The p bonding structure 668 is in direct physical contact with both the p contact 628 and either the p-type layer or a mirror layer 680 in electrical and/or direct physical contact with the p-type layer 673. The mirror layer 680 may comprise a silver layer, and/or a dielectric mirror with conductive vias through the dielectric mirror so that the conductive vias contact the p-type layer 673, electrically connecting the p contact 628 to the p-type layer 673. The n outer bonding structure 664, n center bonding structure 666, and p bonding structure 668 are spaced apart from adjacent ones of one another by the first dielectric 660. For example, in FIG. 6 the leftmost p bonding structure 668 is spaced apart from the n center bonding structure 666 on the left with only the first dielectric 660 in between (which prevents a direct electrical connection between the two); the p contact 628 underneath is in direct physical contact and direct electrical connection with the p bonding structure 668, while being spaced apart from the n center bonding structure 666 so that the two are not in direct physical contact nor direct electrical connection. The n outer bonding structure 664 and n center bonding structure 666 are likewise spaced apart by the first dielectric so that they are not in direct physical contact nor direct electrical connection. Furthermore, the n outer bonding structure 664 and n center bonding structure 666 are spaced apart from the p-type layer 673, the quantum well 675, and the mirror layer 680 by the first dielectric 660.

The n outer contacts 624 and the corresponding n outer bonding structure 664 may be disposed under a mesa 630 etched around the perimeter or part of the perimeter of the n-type layer 670. The n outer bonding structure 664 may be in direct contact with the mesa 630. The top surface of the n outer contacts 624 may overlap partially or completely with the mesa 630 (e.g., their areas when viewed down the third direction Z may partially or completely intersect). Thus the n-type layer 670 has a mesa 630 with a height in a third direction Z (which is perpendicular to the first direction X and the second direction Y) less than an adjacent region in the n-type layer 670 with a greater height. The outer edge of the n outer bonding structure 664 may be flush with an edge of the mesa 630 and/or flush with an outermost edge of the n-type layer 670. However, this is not required, and the n outer bonding structure 664 may extend past the edge of the epitaxial layer 610 or be surrounded by the edge of the epitaxial layer 610.

The n outer bonding structure 664, n center bonding structure 666, and p bonding structure 668 may be made of Cu, Al or Ag and/or any combination. In general, any electrical conductive material can be used. Sheet resistance of this layer is typically low to reduce current spreading losses

The n outer contacts 624, n center contacts 626, and the p contacts 628 may be spaced apart from each other by a gap of silicone or air and/or a second dielectric 662. The second dielectric 662 may be a same or different material as the first dielectric 660. In embodiments of the invention the second dielectric 662 may be omitted.

FIG. 7 depicts one n outer contact 624, one n center contact 626, and one p contact 628. As a result there are only three electrical terminals coming out of the die 600 and connected to a drive circuit. However, this is not required, and there may be more terminals, such as a second n outer contact electrically isolated from a first outer contact to make a total of four electrical terminals. In summary, the two different n current injection paths are connected to two different bonding structures that are connected to two different electrical pads/contacts. In total, the die according to embodiments of the invention may have just three different terminals: one common p contact, one connected to center n Vias and one connected to an n outer n Via bonding structure.

Disposed on the die 610 may be a substrate 658 (e.g., a sapphire platelet or undoped semiconductor material) bonded to a phosphor layer 655 by a glue layer 650. The die with adjustable light emitting area can be either VTF (vertical thin film or embedded contact vertical thin film), CSP (sapphire is still on the epi), or TFFC (Thin film flip chip).

According to embodiments of the invention, FIGS. 8A-8E shows a top view layout and current injection paths of n and p contacts and bonding structures that will be attached to an epitaxial layer, to make a die able to produce a ESL luminance profile (i,e where the luminance gradient varies from one side of the die to an opposite side). In this example, the n outer contact 664 is arranged only as a U-shaped ring rather than along the full mesa etched area, so that it overlaps only part of the mesa 630. That is, the n outer contact 624 only partially surrounds the non-mesa portions of the epitaxial layer and the n center bonding structures 666. The n outer contact 664 may have other shapes, such as extending only along one edge of the die without extending around others, only extending along one corner of the die without fully extending along an entire edge, extending only along part of one edge without meeting the corners, and other similar configurations.

FIG. 8A shows just the layout of the n bonding structure 664 and the center n Vias (n center bonding structure 666). The n center bonding structures 666 show a 3×4 array of center n Vias.

FIG. 8B shows the first dielectric 660, which has openings for the n center bonding structures 666 and the p bonding structure 668. This first dielectric 660 spaces apart and isolates the n and p bonding structures from direct electrical connection with each other.

FIG. 8C show the n outer contact 624, n center contact 626, and p contact 628 disposed below and respectively connected to the n and p bonding structures 664, 666, and 668. The n outer contact 624 and the p contact 628 may be disposed on opposite sides of the die with the n center contact 626 in between. All the contacts may have the same or similar dimensions, although this is not required.

With only three large electrical pads, the die with an adjustable luminance gradient can be connected to the tile with a standard flip chip solder bump.

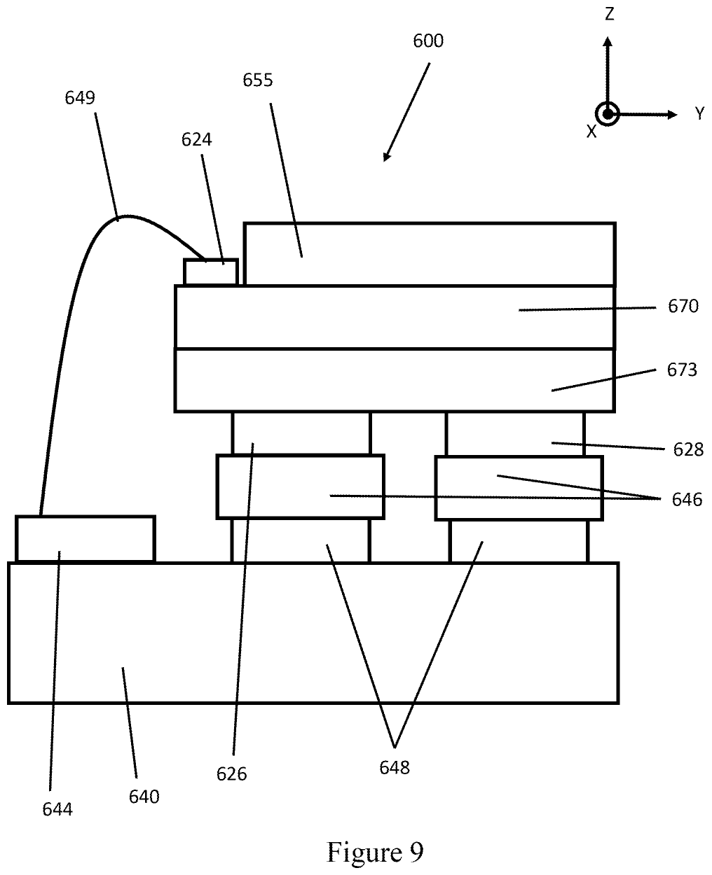

FIG. 9 depicts embodiments of the invention where the die substrate 658 (which may be an undoped semiconductor) can be etched and the n outer contact 624 may provided on top of the epitaxial layer 610 via wire bond 649 to a separated pad area 644 situated the tile 640. That is, the n outer contact 624 is situated on an opposing side from the epitaxial layer 610 as the n center contact 626 and the p contact 628. As a result, the bottom of the epitaxial layer 610 has only two electrical pads which maximize the interconnect area and reduce the reliability risk. These two electrical pads may include the n center contact 626, the p contact 628, and solder 646 connecting the contacts to the tile top metallization layers 648 disposed in direct contact with the tile 640. The tile 640 may be CMOS.

The die with adjustable luminance gradient can be either VTF (vertical thin film or embedded contact vertical thin film), chip-scale package (CSP; sapphire is still on the epi), or TFFC (thin film flip chip).

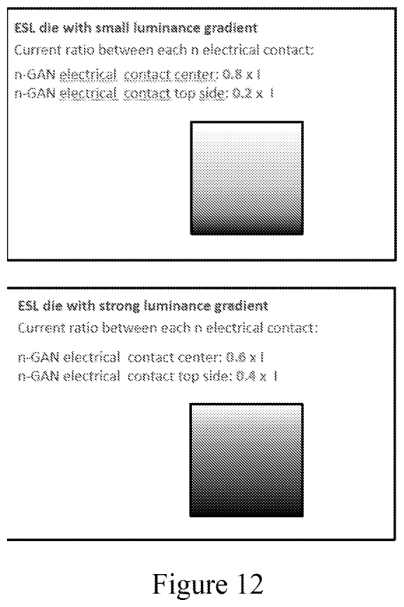

For such dies described above, the peakiness (i.e., the deviation of average luminance of the peak luminance area from the average luminance of the whole light emitting area) can be increased by reducing the part of current injected via the n outer contact 624. For example, if a flat luminance profile may be obtained for a ratio 1/1 between n center current and the n outer current, the ratio may be set to 0.6/0.4 to get a peaky luminance profile. Furthermore, if the die is operating at a current where the V_{f} increase and IQE reduction are not significant, the operator will be free to further increase the ratio between the n center contact current and n outer (top side) contact current, e.g. 0.8/0.2, further increasing peakiness. An example of current driving to get different “degree” of edge shift luminance profile is shown in FIG. 12.

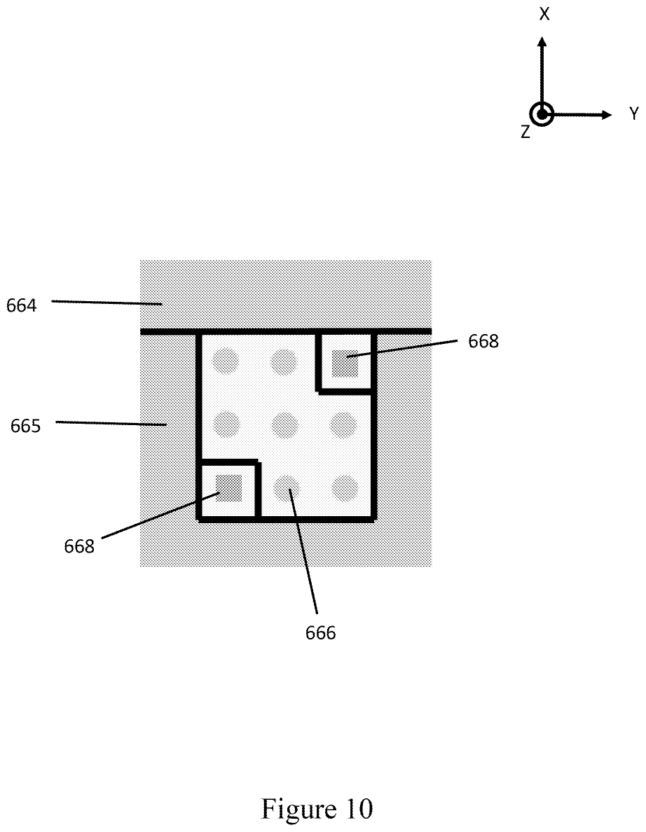

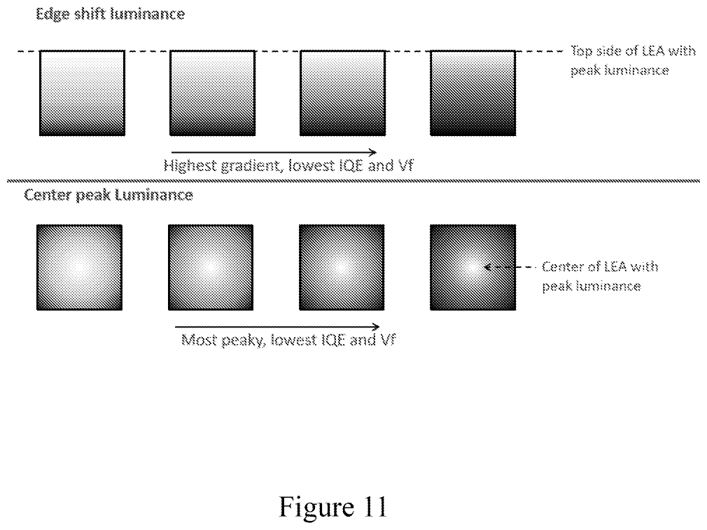

An adjustable luminance gradient die could be made to switch between the ESL and CPL luminance profile. In this case, there may be four electrical terminals total coming out from the die rather than three. Here there are three electrical contacts in the n side that can be independently driven from each other (e.g., by currents of different magnitudes). In other words, these three n sided electrical contacts may be electrically connected to parts of the bonding structure that are electrically isolated from each other by the first dielectric. FIG. 10 depicts this layout: a region with n outer bonding structure 664, a region with n center bonding structure 666, and a region with second n outer bonding structure 665. All of these bonding structures may be segmented to not be in direct physical contact with one another at any point. The n outer bonding structures may together make up an entire perimeter of the die or epitaxial layer, e.g., one extends the length of one edge and the other is in a U-shaped ring. In this case, at least an additional electrical pad may be needed which will cramp pad area under the epitaxial layer. As a consequence, contacting to the tile/submount may have to be done via GGI (gold to gold interconnection) or solder uBump. For example, when most of the current in the die goes through n center bonding structure 666 compared to the rest of the bonding structures in the die, there is a CPL profile with a very peaky center; when the n center bonding structure 666 has most of the current with some current going through both the n outer bonding structure 665 and second n outer bonding structure 665, then there is a CPL profile with moderate peakiness; when most of the current goes through the n outer bonding structure 664 with some current in the n center bonding structure 666, there may be a an ESL profile with peakiness along the edge of the n outer bonding structures 664 (e.g., extending along the Y direction).

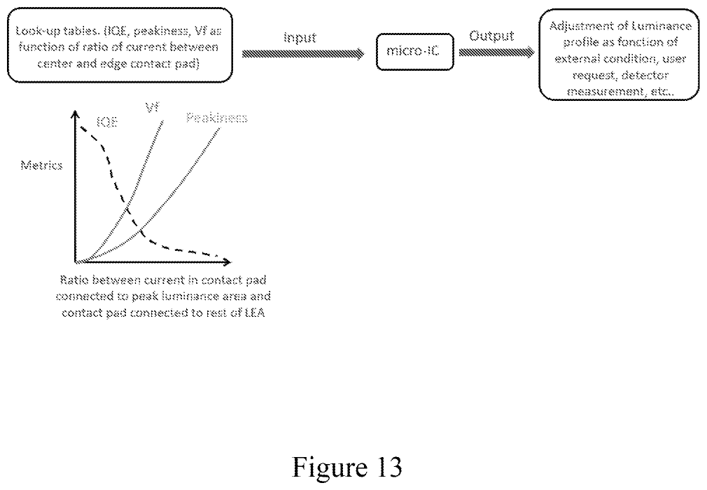

In embodiments of the invention, look-up tables between luminance distribution (peakiness or gradient), Vr increase, and IQE penalty may be provided, so that for example, customers who order the dies and place them together on a package may know how to tune the luminance to their needs. These tables can then be placed into the IC unit (such as a controller on or off the tile 640) to adapt the luminance profile dynamically to external conditions or different driving condition. This principle is illustrated in FIG. 13.

The dies according to embodiments of the invention described above can be built with standard processes. The important step is to get at least three electrically isolated bonding structures: two connected to the n-type layer and one connected to the second doped semi- conductor layer. This could be done by using a shadow mask during deposition or by etching the bonding structure after deposition.

Preferably the first and second dielectric layer will be disposed before and after deposition of the bonding structure to be sure that the bonding structure connects the first doped semi-conductor (i.e., maximum of n Via) without risk of short circuit. However, it is also possible to use only one dielectric layer.

To electrically connect the die to a tile, submount or board, it's simply possible to use a standard flip chip solder bump that is suitable for bonding area larger than 150 μm. For a smaller bonding area, it is possible to use flip chip fine pitch solder bump or flip chip micro bump. If electrical contact area is smaller than 50 μm, it is possible to use Cu pillar bump.

Although the above description describes two or three n sided terminals coming out of the die connected in parallel with one p contact coming out of the die, any descriptions of the n and p side of the terminals coming out of the die (and corresponding bonding structures/semiconductor layers/etc. connected to those terminals) may be inverted. For example, there may be two or three p sided terminals with only one n sided terminal coming out of the die.

This invention can be used in automotive headlamps where a gradient or peaky surface luminance is needed. It can also be used in any application where the surface luminance pattern has to vary dynamically as function of time, as function of external conditions or as function of operating conditions.

This disclosure is illustrative and not limiting. Further modifications will be apparent to one skilled in the art in light of this disclosure and are intended to fall within the scope of the appended claims.

1. A light emitting diode, comprising:
a substrate comprising a first surface extending in a horizontal direction;
a semiconductor diode structure disposed on the substrate and comprising an n-type layer and a p-type layer;
a bonding structure disposed on the semiconductor diode structure, the bonding structure comprising:
at least one n center bonding structure having a first shape extending in the horizontal direction;
an n outer bonding structure spaced apart from the at least one n center bonding structure having a second shape extending in the horizontal direction and different from the first shape; and
a p bonding structure spaced apart from the at least one n center bonding structure and the n outer bonding structure; and
an n center contact electrically connected to the at least one n center bonding structure;
an n outer contact electrically connected to the n outer bonding structure and overlapping the n outer bonding structure in a vertical direction perpendicular to the horizontal direction; and
a p contact electrically connected to the p bonding structure.

2. The light emitting diode of claim 1, wherein the at least one n center bonding structure and the n outer bonding structure are in direct contact with the n-type layer.

3. The light emitting diode of claim 1, wherein the n center contact and the n outer contact are configured to be driven independently by currents of different magnitudes.

4. The light emitting diode of claim 1, wherein the at least one n center bonding structure includes an array of n Vias contacting the semiconductor diode structure with individual areas spaced out from other individual areas of the n Vias at point of direct contact with the n-type layer.

5. The light emitting diode of claim 4, wherein the array is an A×B array where A is from 1 to 10 and B is from 1 to 10.

6. The light emitting diode of claim 4, wherein the array of n Vias forms a shape having a longest dimension shorter than a longest dimension of the n outer bonding structure.

7. The light emitting diode of claim 4, wherein the array of n Vias is completely surrounded by the n outer bonding structure.

8. The light emitting diode of claim 1, wherein the n outer bonding structure is disposed on a mesa etched on the n-type layer.

9. The light emitting diode of claim 8, wherein the n outer bonding structure forms a rectangle.

10. The light emitting diode of claim 8, wherein the n outer bonding structure has a width of 1-50 microns as it extends at least partially around the mesa

11. The light emitting diode of claim 8, wherein the mesa comprises four corners and the n outer bonding structure only surrounds two of the four corners at most

12. The light emitting diode of claim 1, wherein the at least one n center bonding structure and the n outer bonding structure are spaced apart from each other by a first dielectric.

13. The light emitting diode of claim 1, wherein the n center contact, the n outer contact, and the p contact are spaced apart from each other by a second dielectric.

14. The light emitting diode of claim 1, further comprising a second n outer bonding structure spaced apart from the n outer bonding structure, and a second n outer contact spaced apart from the n outer contact.

15. The light emitting diode of claim 1, wherein the n center contact, the n outer contact, and the p contact comprise solder.
